(19) United States
(12) Patent Application Publication
(10) Pub. No.: US 2025/0341545 A1
(43) Pub. Date: Nov. 6, 2025

(54) POWER MODULE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yuichi SAWAHARA, Sagamihara Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/186,731

(22) Filed: Apr. 23, 2025

(30) Foreign Application Priority Data
May 1, 2024 (JP) 2024-074492

(51) Int. Cl. G01R 1/20

(52) U.S. Cl. CPC G01R 1/203

(57) ABSTRACT

According to one embodiment, a power module including a power device, a first conductive pattern, a shunt resistor element, and a second conductive pattern is provided. One end of the first conductive pattern is connected to the power device. The first conductive pattern extends from the power device in at least a first direction. One end of the shunt resistor element in the first direction is connected to the other end of the first conductive pattern. The second conductive pattern is connected to the other end of the shunt resistor element. The second conductive pattern includes a portion. The portion extends in the first direction along the shunt resistor element and the first conductive pattern from a position separated from the shunt resistor element in the second direction. The second direction intersects the first direction.

### CROSS-REFERENCE TO RELATED APPLICATIONS

This application is based upon and claims the benefit of priority from Japanese Patent Application No. 2024-074492, filed on May 1, 2024; the entire contents of which are incorporated herein by reference.

### FIELD

Embodiments described herein relate generally to a power module.

### BACKGROUND

In a power module on which a power device is mounted, a shunt resistor may be inserted into a power loop including the power device. In the power module, it is desirable to appropriately detect the current in the current path using a shunt resistor having a small resistance value in order to minimize the influence on the circuit.

### BRIEF DESCRIPTION OF THE DRAWINGS

FIG. 1 is a plan view illustrating a configuration of a power module in a first embodiment;

FIG. 2 is a cross-sectional view illustrating a configuration of the power module in the first embodiment;

FIG. 3 is a circuit diagram illustrating a configuration of the power module in the first embodiment;

FIG. 4 is a perspective view illustrating a current path near the shunt resistor element in the first embodiment;

FIG. 5 is a plan view illustrating a current path near the shunt resistor element in the first embodiment;

FIG. 6 is a perspective view illustrating cancellation of magnetic flux in the first embodiment;

FIG. 7 is a perspective view illustrating a configuration near a shunt resistor element in a second embodiment;

FIG. 8 is a cross-sectional view illustrating a configuration of a multilayer substrate in the second embodiment;

FIG. 9 is a plan view illustrating a current path near the shunt resistor element in the second embodiment;

FIGS. 10A and 10B are cross-sectional views illustrating a current path in the vicinity of the shunt resistor element in the second embodiment;

FIG. 11 is a cross-sectional view illustrating cancellation of magnetic flux in the second embodiment;

FIG. 12 is a perspective view illustrating a configuration near a shunt resistor element in a third embodiment;

FIG. 13 is a plan view illustrating a current path near the shunt resistor element in the third embodiment;

FIGS. 14A and 14B are cross-sectional views illustrating a current path in the vicinity of the shunt resistor element in the third embodiment;

FIG. 15 is a plan view illustrating a current path near a shunt resistor element in a fourth embodiment;

FIG. 16 is a cross-sectional view illustrating a current path in the vicinity of the shunt resistor element in the fourth embodiment;

FIG. 17 is a plan view illustrating a current path near a shunt resistor element in a fifth embodiment;

FIG. 18 is a cross-sectional view illustrating a current path in the vicinity of the shunt resistor element in the fifth embodiment; and

FIG. 19 is a plan view illustrating a current path near a shunt resistor element in a sixth embodiment.

### DETAILED DESCRIPTION

In general, according to one embodiment, there is provided a power module including a power device, a first conductive pattern, a shunt resistor element and a second conductive pattern. The first conductive pattern has one end connected to the power device and extending from the power device in at least a first direction. The shunt resistor element has one end in the first direction connected to an other end of the first conductive pattern. The second conductive pattern is electrically connected to an other end of the shunt resistor element and including a portion extending in the first direction along the shunt resistor element and the first conductive pattern from a position separated from the shunt resistor element in a second direction intersecting the first direction.

Exemplary embodiments of a power module will be explained below in detail with reference to the accompanying drawings. The present invention is not limited to the following embodiments.

### First Embodiment

In a power module according to a first embodiment, a power device is mounted, a shunt resistor is inserted into a current path including the power device, and a device for appropriately detecting a current in a current path using the shunt resistor is provided.

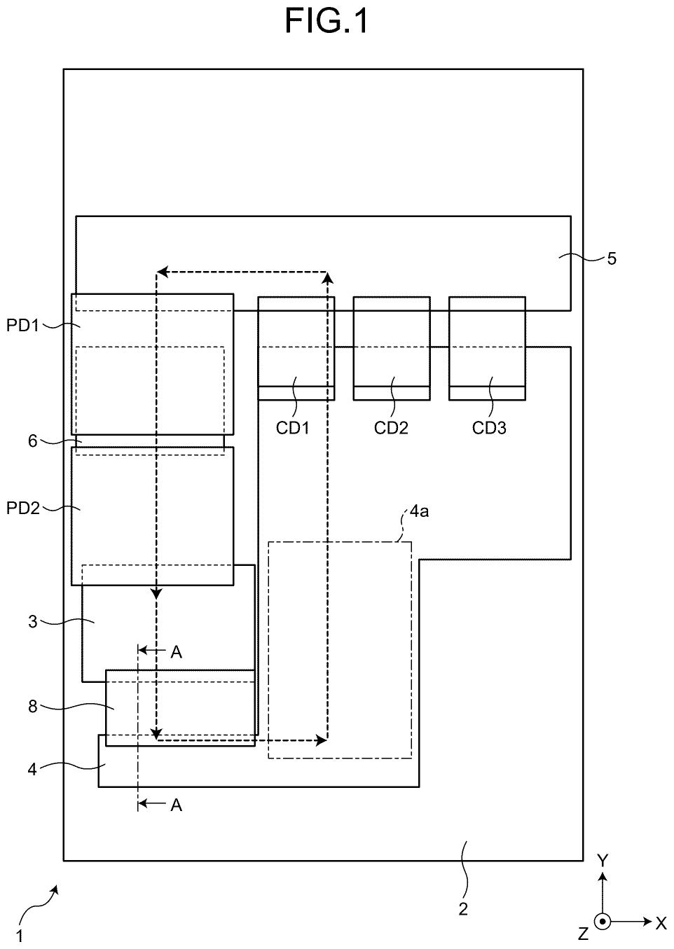

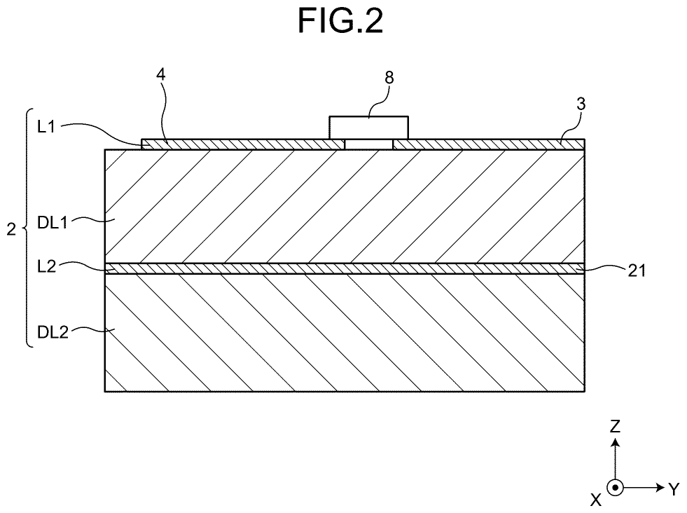

A power module 1 can be configured as illustrated in FIGS. 1 and 2. FIG. 1 is a plan view illustrating a configuration of the power module 1. FIG. 2 is a cross-sectional view illustrating the configuration of the power module 1, and illustrates a cross section taken along line A-A in FIG. 1. Hereinafter, a direction perpendicular to the main surface of a substrate 2 is referred to as a Z direction, and two directions orthogonal to each other in a plane perpendicular to the Z direction are referred to as an X direction and a Y direction.

The power module 1 includes a multilayer substrate 2, a shunt resistor element 8, power devices PD1 and PD2, and capacitive devices CD1 to CD3.

In the multilayer substrate 2, as illustrated in FIG. 2, an insulating layer DL2, a wiring layer L2, an insulating layer DL1, and a wiring layer L1 are sequentially stacked in the Z direction.

The wiring layer L2 extends in the XY direction. The wiring layer L2 includes a conductive pattern 21. The conductive pattern 21 is formed of a conductive material, and may be formed of, for example, a material containing metal as a main component, or may be formed of a semiconductor to which conductivity is imparted.

The wiring layer L1 extends in the XY direction. The wiring layer L1 includes a conductive pattern 3, a conductive pattern 4, a conductive pattern 5, and a conductive pattern 6 illustrated in FIG. 1. The shunt resistor element 8 is disposed in the wiring layer L1. The power devices PD1 and PD2 are disposed in the wiring layer L1. The capacitive devices CD1 to CD3 are disposed in the wiring layer L1.

The power device PD1 is electrically connected between the conductive pattern 5 and the conductive pattern 6. The power device PD1 may have a substantially rectangular shape in XY plan view. The power device PD1 may have the Y direction as the longitudinal direction and the X direction as the lateral direction. The power device PD1 has one end connected to the conductive pattern 5 and the other end connected to the conductive pattern 6 in the Y direction.

The conductive pattern 6 is electrically connected between the power device PD1 and the power device PD2. The conductive pattern 6 is formed of a conductive material, and may be formed of, for example, a material containing metal as a main component, or may be formed of a semiconductor to which conductivity is imparted. The conductive pattern 6 extends at least in the Y direction. The conductive pattern 6 may further extend in the X direction. The conductive pattern 6 may have a substantially rectangular shape in XY plan view. In the conductive pattern 6, one end on the −Y side is electrically connected to the conductive pattern 3 via the power device PD2, and the other end on the +Y side is electrically connected to the conductive pattern 5 via the power device PD1.

The power device PD2 is electrically connected between the conductive pattern 6 and the conductive pattern 3. The power device PD2 may have a substantially rectangular shape in XY plan view. The power device PD2 may have the X direction as the longitudinal direction and the Y direction as the lateral direction. The power device PD2 has one end connected to the conductive pattern 6 and the other end connected to the conductive pattern 3 in the Y direction.

The conductive pattern 3 is electrically connected between the power device PD2 and the shunt resistor element 8 in the Y direction. The conductive pattern 3 is formed of a conductive material, and may be formed of, for example, a material containing metal as a main component, or may be formed of a semiconductor to which conductivity is imparted. The conductive pattern 3 extends at least in the Y direction. The conductive pattern 3 may further extend in the X direction. The conductive pattern 3 may have a substantially rectangular shape in XY plan view. In the conductive pattern 3, one end on the +Y side is connected to the power device PD2, and the other end on the −Y side is connected to one end of the shunt resistor element 8.

The shunt resistor element 8 is electrically connected between the conductive pattern 3 and the conductive pattern 4 in the Y direction. The shunt resistor element 8 extends at least in the Y direction. The shunt resistor element 8 may further extend in the X direction. In the shunt resistor element 8, one end on the +Y side is connected to the conductive pattern 3, and the other end on the −Y side is connected to one end of the conductive pattern 4.

The conductive pattern 4 is electrically connected between the shunt resistor element 8 and the capacitive devices CD1 to CD3 in the XY direction. The conductive pattern 4 is formed of a conductive material, and may be formed of, for example, a material containing metal as a main component, or may be formed of a semiconductor to which conductivity is imparted. The conductive pattern 4 includes a portion 4a. The portion 4a extends in the Y direction along the shunt resistor element 8 and the conductive pattern 3 from a position separated from the shunt resistor element 8 in the X direction.

One end of the conductive pattern 4 is connected to the other end of the shunt resistor element 8 in the Y direction. The conductive pattern 4 may have a substantially S-shape in XY plan view. The conductive pattern 4 extends to a position (for example, a position separated to the +X side) separated from the other end of the shunt resistor element 8 in the X direction. The conductive pattern 4 is bent in the Y direction from the position and extends in the Y direction along the shunt resistor element 8 and the conductive pattern 3. The other end of the conductive pattern 4 is connected to the conductive pattern 5 via the capacitive devices CD1 to CD3. The conductive pattern 4 may have a substantially S-shape in XY plan view. The conductive pattern 4 has one end disposed on the −Y side and the other end disposed on the +Y side.

The capacitive devices CD1 to CD3 are electrically connected between the conductive pattern 5 and the conductive pattern 4. Each of the capacitive devices CD1 to CD3 may have a substantially rectangular shape in XY plan view. Each of the capacitive devices CD1 to CD3 may have the Y direction as the longitudinal direction and the X direction as the lateral direction. One end of each of the capacitive devices CD1 to CD3 is connected to the conductive pattern 4, and the other end is connected to the conductive pattern 5 in the Y direction.

The conductive pattern 5 is electrically connected between the power device PD1 and the capacitive devices CD1 to CD3. The conductive pattern 5 is formed of a conductive material, and may be formed of, for example, a material containing metal as a main component, or may be formed of a semiconductor to which conductivity is imparted. The conductive pattern 5 extends mainly in the X direction. The conductive pattern 5 may have a substantially lateral I-shape in XY plan view. In the conductive pattern 5, +X side and −Y side portions are connected to the capacitive devices CD1 to CD3, and −X side and −Y side portions are connected to the power device PD1.

Accordingly, in the power module 1, as indicated by dotted arrows, a current path of a loop of the conductive pattern 5→the power device PD1→the conductive pattern 6→the power device PD2→the conductive pattern 3→the shunt resistor element 8→the conductive pattern 4→the capacitive devices CD1 to CD3→the conductive pattern 5 is formed.

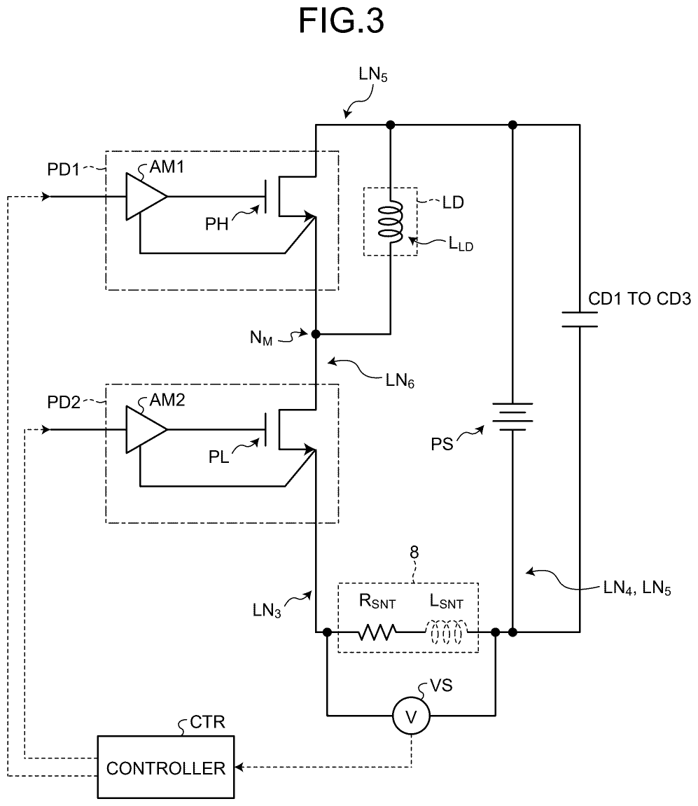

For example, an equivalent circuit of the power module 1 is as illustrated in FIG. 3. FIG. 3 is a circuit diagram illustrating a configuration of the power module 1.

The power module 1 includes power devices PD1 and PD2, a shunt resistor element 8, a power supply PS, and a controller CTR. In the power module 1, a current path of the power supply PS and the capacitive elements CD1 to CD3→the power device PD1→the power device PD2→the shunt resistor element 8→the power supply PS and the capacitive elements CD1 to CD3 is formed.

The power supply PS is a DC power supply and generates DC power. The power supply PS outputs a DC voltage with the other end as a reference from one end. One end of the power supply PS is referred to as a high voltage side, and the other end is referred to as a low voltage side.

The power device PD1 is connected in series between the power supply PS, the capacitive elements CD1 to CD3, and the power device PD2. The power device PD1 includes a driver AM1 and a transistor PH. The transistor PH is an N-type transistor and may be an NMOSFET.

The load LD is connected in parallel to the power device PD1. The load LD may include at least one of a resistive component, a capacitive component, or an inductive component. In FIG. 3, a load LD including an inductive component LLD is illustrated.

The power device PD2 is connected in series between the power device PD1 and the shunt resistor element 8. The power device PD2 includes a driver AM2 and a transistor PL. The transistor PL is an N-type transistor and may be an NMOSFET.

The shunt resistor element 8 is connected in series between the power device PD2, the power supply PS, and the capacitive elements CD1 to CD3. The shunt resistor element 8 includes a resistive component R_{SNT} and further includes a parasitic inductive component L_{SNT}. A voltage sensor VS is connected to both ends of the shunt resistor element 8. The voltage sensor VS detects a voltage generated across the shunt resistor element 8.

The controller CTR receives the detection value of the voltage sensor VS and obtains the current flowing through the shunt resistor element 8 according to the detection value of the voltage sensor VS. As a result, the controller CTR detects the current flowing through the shunt resistor element 8. The controller CTR performs switching control of the power devices PD1 and PD2 according to the current flowing through the shunt resistor element 8. The controller CTR may perform switching control of the power devices PD1 and PD2 so that the current flowing through the shunt resistor element 8 approaches the target value. As a result, DC power from the power supply PS can be converted into AC power by the power devices PD1 and PD2 and supplied to the load LD.

At this time, in order to improve the detection accuracy of the current flowing through the shunt resistor element 8, it is desirable that the parasitic inductive component L_{SNT} included in the shunt resistor element 8 is relatively smaller than the resistive component R_{SNT}.

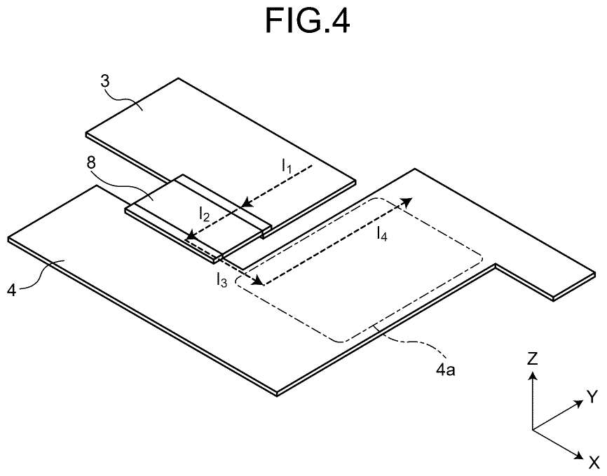

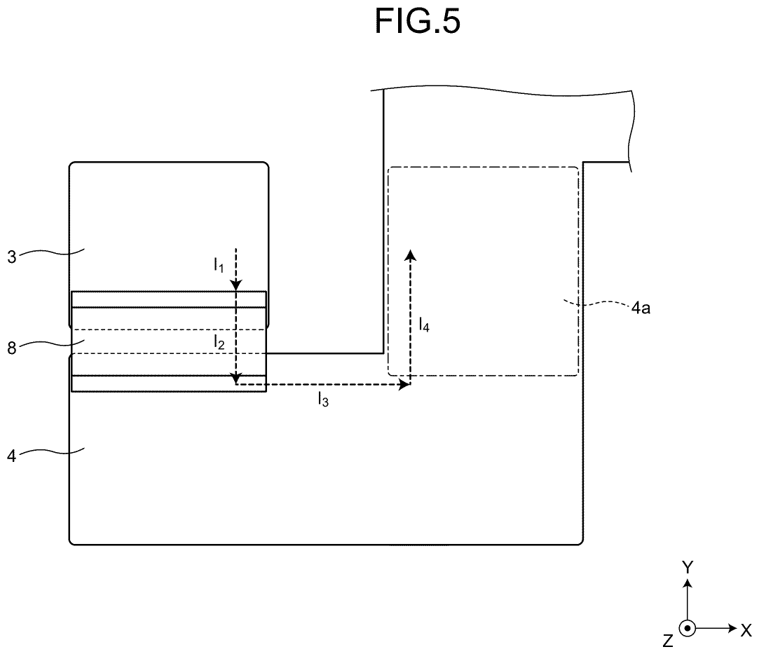

On the other hand, in the power module 1, as illustrated in FIGS. 4 and 5, a substantially U-shaped current path is formed in XY plan view by the conductive pattern 3, the shunt resistor element 8, and the conductive pattern 4. FIG. 4 is a perspective view illustrating a configuration near the shunt resistor element 8. FIG. 5 is an XY plan view illustrating a current path near the shunt resistor element 8.

The currents flowing through the conductive pattern 3, the shunt resistor element 8, the portion on the −Y side in the conductive pattern 4, and the portion 4a in the conductive pattern 4 are denoted as I₁, I₂, I₃, and I₄, respectively.

The current I₁ flows mainly in the −Y direction. The current I₂ flows mainly in the −Y direction. The current I₃ flows mainly in the +X direction. The current I₄ flows mainly in the +Y direction. A substantially U-shaped current path opened on the +Y side is formed by the currents I₁ to I₄. In the current path in the planar direction (XY direction), the current I₂ and the current I₄ are in opposite directions.

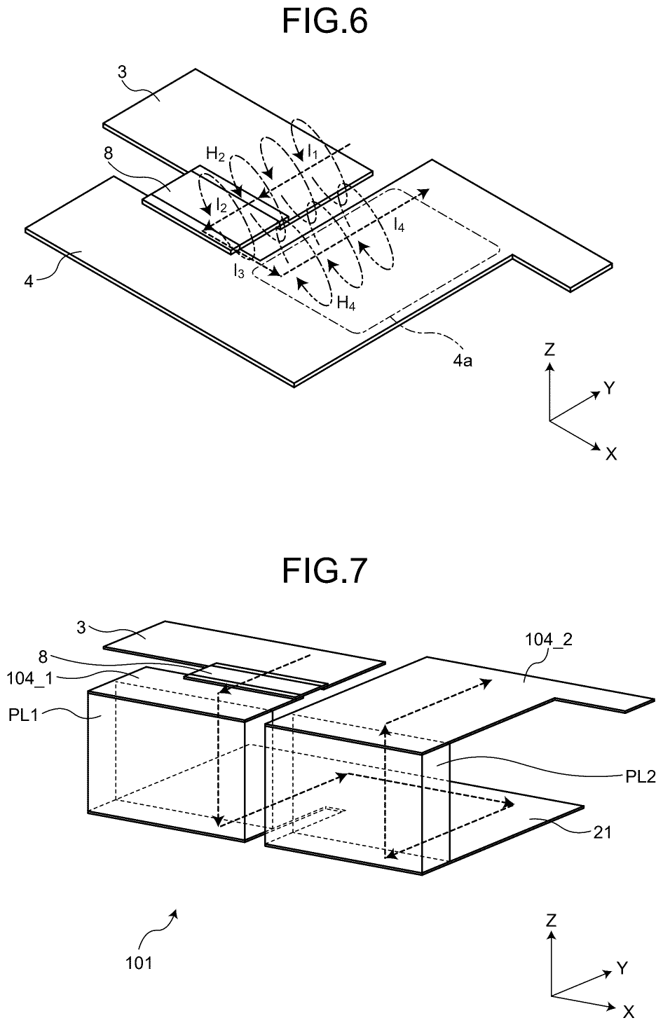

The current I₂ generates a clockwise magnetic flux H₂ when viewed from the +Y direction as illustrated in FIG. 6 according to the parasitic inductive component L_{SNT} of the shunt resistor element 8. FIG. 6 is a perspective view illustrating cancellation of magnetic flux. The current I₄ flows in a direction opposite to that of the current I₂, and generates a magnetic flux H₄ in the opposite direction. The current I₄ generates a clockwise magnetic flux H₄ when viewed from the −Y direction.

As a result, since the magnetic flux H₂ can be canceled by the magnetic flux H₄, the parasitic inductive component LANT included in the resistor element 8 can be equivalently weakened. As a result, the detection accuracy of the voltage across the shunt resistor element 8 by the voltage sensor VS can be improved, and accordingly, the detection accuracy of the current flowing through the shunt resistor element 8 can be improved.

As described above, in the first embodiment, in the power module 1, the conductive pattern 4 includes the portion 4a extending in the Y direction along the shunt resistor element 8 and the conductive pattern 3 from the position separated from the shunt resistor element 8 in the X direction. As a result, the current I₂ flowing through the shunt resistor element 8 and the current I₄ flowing through the portion 4a can be reversed, and the magnetic flux H₂ generated by the current I₂ can be canceled by the magnetic flux H₄ generated by the current I₄. As a result, the parasitic inductive component L_{SNT} included in the resistor element 8 can be equivalently weakened, the detection accuracy of the voltage across the shunt resistor element 8 by the voltage sensor VS can be improved, and accordingly, the detection accuracy of the current flowing through the shunt resistor element 8 can be improved. As a result, the controller CTR appropriately performs switching control of the power devices PD1 and PD2 according to the current flowing through the shunt resistor element 8. Therefore, in the power module 1, the power devices PD1 and PD2 can convert DC power from the power supply PS into AC power at an appropriate level and supply the AC power to the load LD.

### Second Embodiment

Next, a power module according to a second embodiment will be described. Hereinafter, portions different from those of the first embodiment will be mainly described.

Although in the first embodiment, a configuration in which a reverse current is formed in a current path in a planar direction to cancel magnetic flux is exemplified, in the second embodiment, a configuration in which a reverse current is formed in a three-dimensional current path using two wiring layers to cancel magnetic flux is exemplified.

For example, in a power module 101, as illustrated in FIG. 7, a current path in which multiple substantially U shapes is three-dimensionally combined may be formed. FIG. 7 is a perspective view illustrating a configuration near the shunt resistor element 8.

The configuration illustrated in FIG. 7 is different from the configuration illustrated in FIG. 4 in that the conductive pattern 4 is divided into a conductive pattern 104_1 on the −X side and a conductive pattern 104_2 on the +X side, the conductive pattern 104_1 and the conductive pattern 21 are connected by a conductive plug PL1, and the conductive pattern 104_2 and the conductive pattern 21 are connected by a conductive plug PL2.

The conductive pattern 104_1 is arranged on the −Y side of the shunt resistor element 8. One end of the conductive pattern 104_1 is electrically connected to the other end of the shunt resistor element 8 in the Y direction. The conductive pattern 104_1 extends in the Y direction from the other end of the shunt resistor element 8 and reaches the XY position of the conductive plug PL1. The conductive pattern 104_1 may have a substantially rectangular shape in XY plan view. The other end of the conductive pattern 104_1 is connected to the conductive plug PL1.

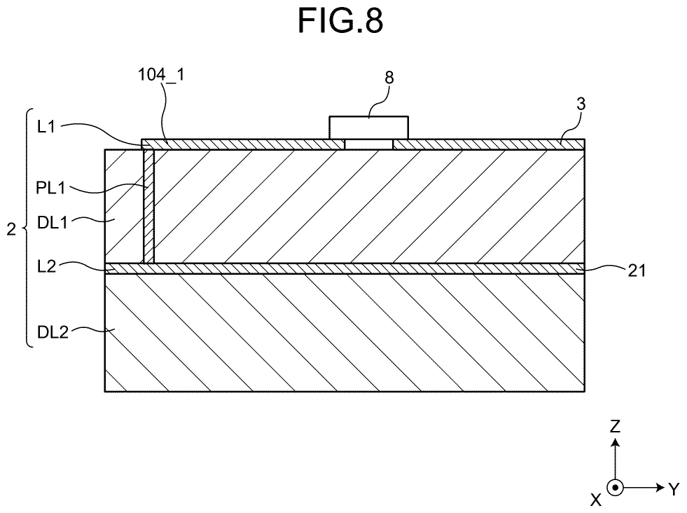

As illustrated in FIGS. 7 and 8, the conductive plug PL1 is disposed between the conductive pattern 104_1 and the conductive pattern 21 in the Z direction. FIG. 8 is a cross-sectional view illustrating a configuration of a multilayer substrate. The conductive plug PL1 is electrically connected between the conductive pattern 104_1 and the conductive pattern 21. In the conductive plug PL1, one end on the +Z side is connected to the conductive pattern 104_1, extends in the Z direction, and the other end on the −Z side is connected to the conductive pattern 21. In the YZ cross-sectional view (see FIG. 8) passing through the conductive plug PL1, the structure including the conductive pattern 104_1, the conductive plug PL1, and the conductive pattern 21 forms a substantially U-shape with the +Y side opened.

The conductive pattern 21 illustrated in FIG. 7 is disposed substantially on the +Y side with respect to the conductive plugs PL1 and PL2. The conductive pattern 21 is electrically connected between the conductive plug PL1 and the conductive plug PL2. The conductive pattern 21 forms a substantially U-shape with the −Y side opened in XY plan view. The conductive pattern 21 extends to a position (for example, a position separated to the +Y side) separated from the other end of the conductive plug PL1 in the Y direction. The conductive pattern 21 is bent in the X direction from the position and extends to a position (for example, a position separated to the +X side) separated in the X direction. The conductive pattern 21 is bent in the Y direction from the position and extends to one end of the conductive plug PL2.

As illustrated in FIG. 7, the conductive plug PL2 is disposed between the conductive pattern 104_2 and the conductive pattern 21 in the Z direction. The conductive plug PL2 is electrically connected between the conductive pattern 104_2 and the conductive pattern 21. In the conductive plug PL2, one end on the +Z side is connected to the conductive pattern 104_2, extends in the Z direction, and the other end on the −Z side is connected to the conductive pattern 21. In the YZ cross-sectional view passing through the conductive plug PL2, the structure including the conductive pattern 104_2, the conductive plug PL2, and the conductive pattern 21 forms a substantially U-shape with the +Y side opened.

The configuration illustrated in FIG. 7 forms a current path in which three substantially U-shaped shapes are three-dimensionally combined as indicated by dotted arrows. The three substantially U-shapes include a substantially U-shape in which the +Y side is opened in the YZ cross-sectional view through the conductive plug PL1, a U-shape in which the −Y side is opened in XY plan view, and a substantially U-shape in which the +Y side is opened in the YZ cross-sectional view through the conductive plug PL2.

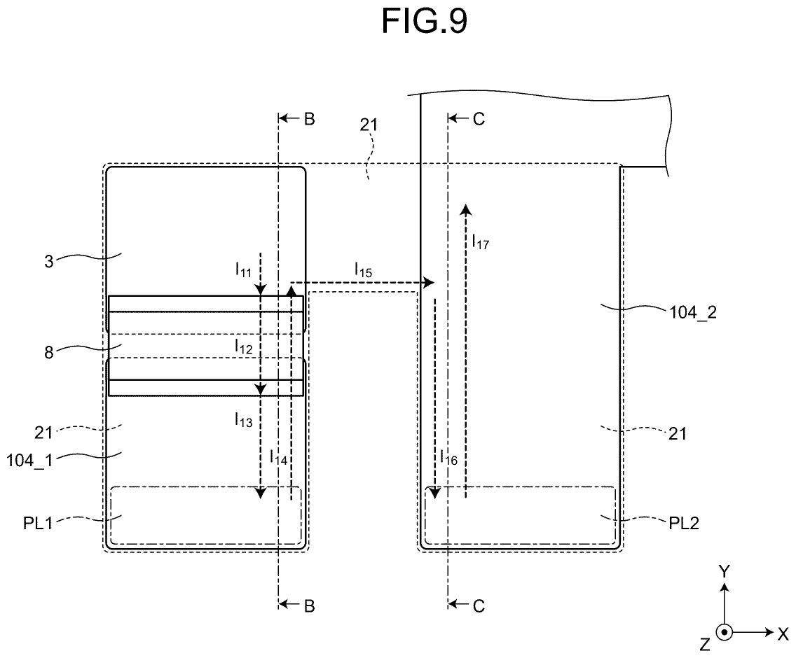

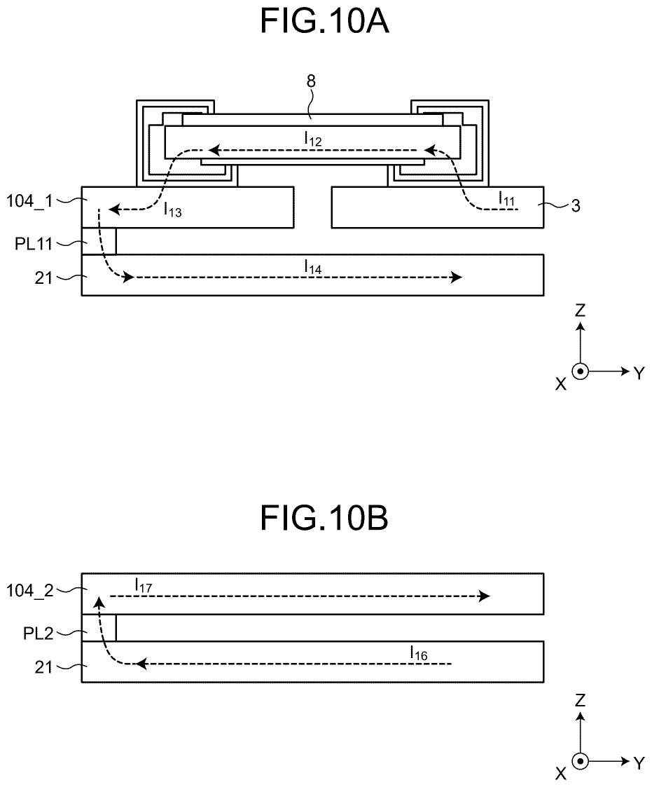

That is, in the power module 101, as illustrated in FIGS. 9, 10A, and 10B, a current path in which three substantially U-shapes are three-dimensionally combined is formed by the conductive pattern 3, the shunt resistor element 8, the conductive pattern 104_1, the conductive plug PL1, the conductive pattern 21, the conductive plug PL2, and the conductive pattern 104_2. FIG. 9 is an XY plan view illustrating a configuration near the shunt resistor element 8. FIGS. 10A and 10B are YZ cross-sectional views illustrating a current path in the vicinity of the shunt resistor element 8. FIG. 10A is a YZ cross-sectional view passing through the shunt resistor element 8, and illustrates a cross section of FIG. 9 taken along line B-B. FIG. 10B is a YZ cross-sectional view not passing through the shunt resistor element 8, and illustrates a cross section taken along line C-C in FIG. 9.

The currents flowing through the conductive pattern 3, the shunt resistor element 8, the conductive pattern 104_1, the −X side portion of the conductive pattern 21, the −Y side portion of the conductive pattern 21, the +X side portion of the conductive pattern 21, and the conductive pattern 104_2 are denoted as I₁₁, I₁₂, I₁₃, I₁₄, I₁₅, I₁₆, and I₁₇, respectively.

The current I₁₁ flows mainly in the −Y direction. The current I₁₂ flows mainly in the −Y direction. The current I₁₃ flows mainly in the −Y direction. The current I₁₄ flows mainly in the +Y direction. The currents I₁₁ to I₁₄ form a substantially U-shaped current path in the vertical direction (YZ direction) with the +Y side opened. In this vertical current path, the current I₁₂ and the current I₁₄ are in opposite directions.

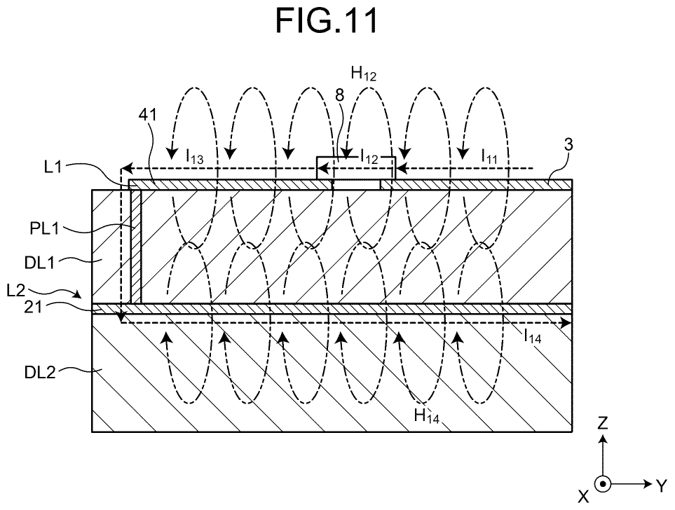

The current I₁₂ generates a clockwise magnetic flux H₁₂ when viewed from the +Y direction as illustrated in FIG. 11 according to the parasitic inductive component L_{SNT} of the shunt resistor element 8. FIG. 11 is a cross-sectional view illustrating cancellation of magnetic flux. The current I₁₄ flows in a direction opposite to that of the current I₁₂, and generates a magnetic flux H₁₄ in the opposite direction. The current I₁₄ generates a clockwise magnetic flux H₁₄ when viewed from the −Y direction.

The current I₁₅ flows mainly in the +X direction. The current I₁₆ flows mainly in the −Y direction. The current I₁₇ flows mainly in the +Y direction. The currents I₁₁ to I₁₇ form a three-dimensional current path in which three substantially U-shapes are combined. In this three-dimensional current path, in addition to the current I₁₂ and the current I₁₄ being in opposite directions, the current I₁₂ and the current I₁₇ are in opposite directions.

The current I₁₂ generates a clockwise magnetic flux H₁₂ when viewed from the +Y direction according to the parasitic inductive component L_{SNT} of the shunt resistor element 8. The current I₁₇ flows in a direction opposite to that of the current I₁₂, and generates a magnetic flux H₁₇ (not illustrated) in the opposite direction. The current I₁₇ generates a clockwise magnetic flux H₁₇ when viewed from the −Y direction.

As a result, since the magnetic flux H₁₂ can be canceled by the magnetic flux H₁₇ in addition to being canceled by the magnetic flux H₁₄, it is possible to further weaken the parasitic inductive component L_{SNT} of the shunt resistor element 8 equivalently.

As described above, in the second embodiment, the power module 101 forms multiple currents in a direction opposite to the current flowing through the shunt resistor element 8 in the three-dimensional current path using the two wiring layers, and may cancel the magnetic flux by the current of the shunt resistor element 8 with the magnetic flux by the multiple currents in the opposite direction. As a result, the parasitic inductive component L_{SNT} of the shunt resistor element 8 can be further weakened, and the detection accuracy of the voltage across the shunt resistor element 8 by the voltage sensor VS can be further improved. Accordingly, the detection accuracy of the current flowing through the shunt resistor element 8 can be further improved.

### Third Embodiment

Next, a power module according to a third embodiment will be described. Hereinafter, portions different from those of the first embodiment and the second embodiment will be mainly described.

Although in the second embodiment, a configuration in which a reverse current is formed in a three-dimensional current path using two wiring layers to cancel magnetic flux is exemplified, in the third embodiment, a configuration in which a reverse current is formed in a three-dimensional current path using a multilayer wiring layer to cancel magnetic flux is exemplified.

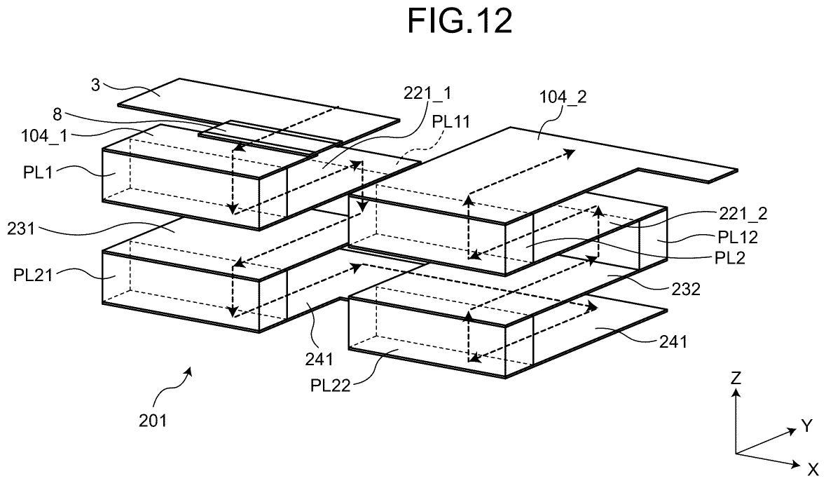

For example, in a power module 201, as illustrated in FIG. 12, a current path in which a large number of substantially U shapes are three-dimensionally combined may be formed. FIG. 12 is a perspective view illustrating a configuration near the shunt resistor element 8.

The configuration illustrated in FIG. 12 is configured by applying the following changes to the configuration illustrated in FIG. 7. The conductive pattern 21 is divided into a conductive pattern 221_1 on the −X side and a conductive pattern 221_2 on the +X side. Conductive patterns 231 and 232 of a wiring layer L3 and a conductive pattern 241 of a wiring layer L4 are added. The conductive pattern 221_1 and the conductive pattern 231 are connected by a conductive plug PL11 on the +Y side, and the conductive pattern 231 and the conductive pattern 241 are connected by a conductive plug PL21 on the −Y side. The conductive pattern 241 and the conductive pattern 232 are connected by a conductive plug PL22 on the −Y side, and the conductive pattern 232 and the conductive pattern 221_2 are connected by a conductive plug PL12 on the +Y side.

The conductive pattern 221_1 is disposed between the conductive plug PL1 and the conductive plug PL11 in the Y direction. The conductive pattern 221_1 is electrically connected between the conductive plug PL1 and the conductive plug PL11. In the conductive pattern 221_1, one end on the −Y side is connected to the conductive plug PL1, extends in the Y direction, and the other end on the +Y side is connected to the conductive plug PL11.

The conductive plug PL11 is disposed between the conductive pattern 221_1 and the conductive pattern 231 in the Z direction. The conductive plug PL11 is electrically connected between the conductive pattern 221_1 and the conductive pattern 231. One end of the conductive plug PL11 on the +Z side is connected to the conductive pattern 221_1, extends in the Z direction, and the other end on the −Z side is connected to the conductive pattern 231. In the YZ cross-sectional view passing through the conductive plug PL11, the conductive pattern 221_1, the conductive plug PL11, and the conductive pattern 231 form a substantially U-shape with the −Y side opened.

The conductive pattern 231 is disposed between the conductive plug PL11 and the conductive plug PL21 in the Y direction. The conductive pattern 231 is electrically connected between the conductive plug PL11 and the conductive plug PL21. One end of the conductive pattern 231 on the +Y side is connected to the conductive plug PL11, extends in the Y direction, and the other end on the −Y side is connected to the conductive plug PL21.

The conductive plug PL21 is disposed between the conductive pattern 231 and the conductive pattern 241 in the Z direction. The conductive plug PL21 is electrically connected between the conductive pattern 231 and the conductive pattern 241. One end of the conductive plug PL21 on the +Z side is connected to the conductive pattern 231, extends in the Z direction, and the other end on the −Z side is connected to the conductive pattern 241. In the YZ cross-sectional view passing through the conductive plug PL21, the conductive pattern 231, the conductive plug PL21, and the conductive pattern 241 form a substantially U-shape with the +Y side opened.

The conductive pattern 241 is disposed substantially on the +Y side with respect to the conductive plugs PL21 and PL22. The conductive pattern 241 is electrically connected between the conductive plug PL21 and the conductive plug PL22. The conductive pattern 241 forms a substantially U-shape with the −Y side opened in XY plan view. The conductive pattern 241 extends to a position (for example, a position separated to the +Y side) separated from the other end of the conductive plug PL21 in the Y direction. The conductive pattern 241 is bent in the X direction from the position and extends to a position (for example, a position separated to the +X side) separated in the X direction. The conductive pattern 241 is bent in the Y direction from the position and extends to one end of the conductive plug PL22.

The conductive plug PL22 is disposed between the conductive pattern 232 and the conductive pattern 241 in the Z direction. The conductive plug PL22 is electrically connected between the conductive pattern 232 and the conductive pattern 241. One end of the conductive plug PL22 on the +Z side is connected to the conductive pattern 232, extends in the Z direction, and the other end on the −Z side is connected to the conductive pattern 241. In the YZ cross-sectional view passing through the conductive plug PL22, the conductive pattern 232, the conductive plug PL22, and the conductive pattern 241 form a substantially U-shape with the +Y side opened.

The conductive pattern 232 is disposed between the conductive plug PL12 and the conductive plug PL22 in the Y direction. The conductive pattern 232 is electrically connected between the conductive plug PL12 and the conductive plug PL22. One end of the conductive pattern 232 on the +Y side is connected to the conductive plug PL12, extends in the Y direction, and the other end on the −Y side is connected to the conductive plug PL22.

The conductive plug PL12 is disposed between the conductive pattern 221_2 and the conductive pattern 232 in the Z direction. The conductive plug PL12 is electrically connected between the conductive pattern 221_2 and the conductive pattern 232. One end of the conductive plug PL12 on the +Z side is connected to the conductive pattern 221_2, extends in the Z direction, and the other end on the −Z side is connected to the conductive pattern 232. In the YZ cross-sectional view passing through the conductive plug PL12, the conductive pattern 221_2, the conductive plug PL12, and the conductive pattern 232 form a substantially U-shape with the −Y side opened.

The conductive pattern 221_2 is disposed between the conductive plug PL2 and the conductive plug PL12 in the Y direction. The conductive pattern 221_2 is electrically connected between the conductive plug PL2 and the conductive plug PL12. In the conductive pattern 221_2, one end on the −Y side is connected to the conductive plug PL2, extends in the Y direction, and the other end on the +Y side is connected to the conductive plug PL12.

The configuration illustrated in FIG. 12 forms a current path in which seven substantially U-shapes are three-dimensionally combined as indicated by dotted arrows. The seven substantially U-shapes include a substantially U-shape in which the +Y side is opened in the YZ cross-sectional view through the conductive plug PL1, a substantially U-shape in which the −Y side is opened in the YZ cross-sectional view through the conductive plug PL11, a substantially U-shape in which the +Y side is opened in the YZ cross-sectional view through the conductive plug PL21, a U-shape in which the −Y side is opened in XY plan view, a substantially U-shape in which the +Y side is opened in the YZ cross-sectional view through the conductive plug PL22, a substantially U-shape in which the −Y side is opened in the YZ cross-sectional view through the conductive plug PL12, and a substantially U-shape in which the +Y side is opened in the YZ cross-sectional view through the conductive plug PL2.

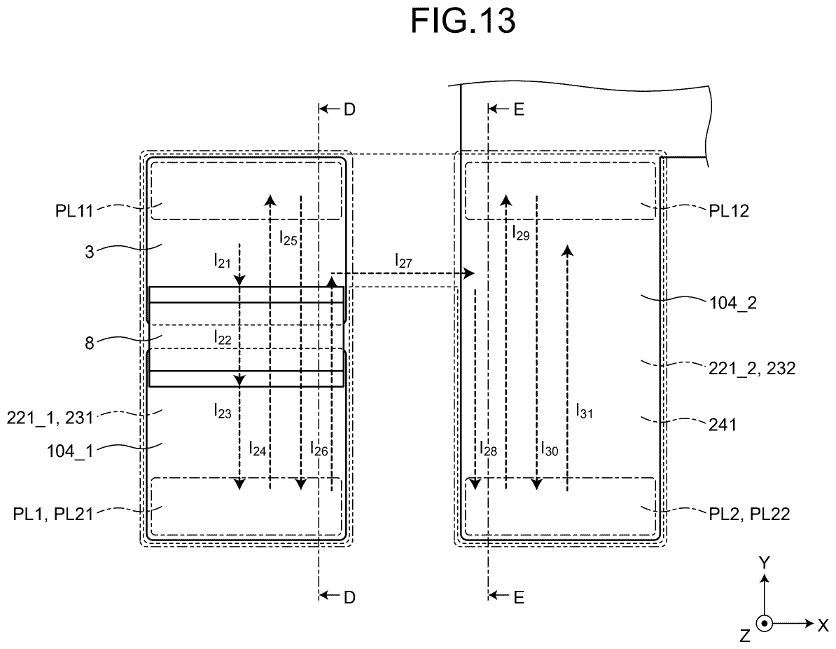

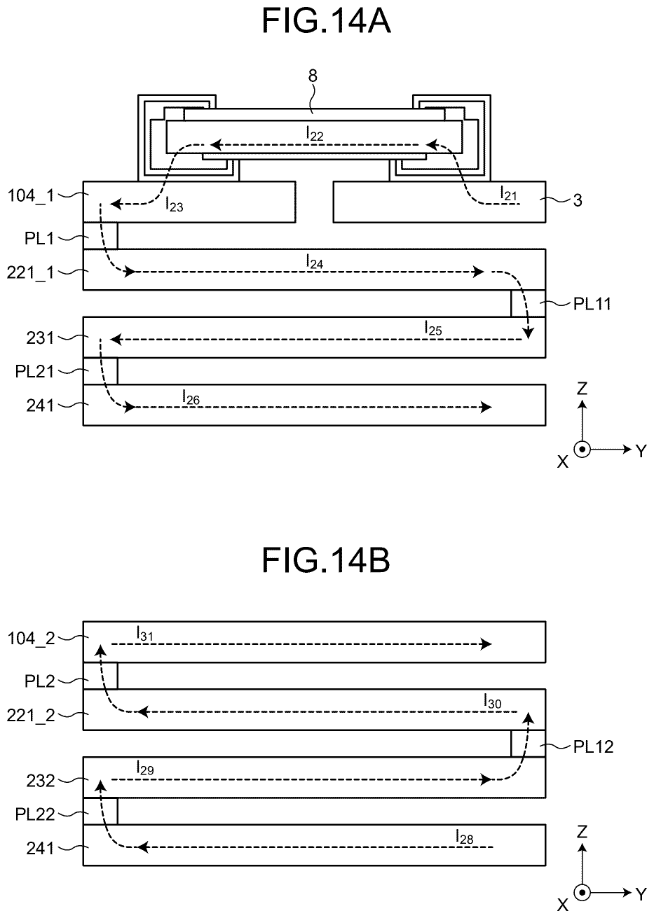

That is, in the power module 201, as illustrated in FIGS. 13, 14A, and 14B, a current path in which seven substantially U-shapes are three-dimensionally combined is formed by the conductive pattern 3, the shunt resistor element 8, the conductive pattern 104_1, the conductive plug PL1, the conductive pattern 221_1, the conductive plug PL11, the conductive pattern 231, the conductive plug PL21, the conductive pattern 241, the conductive plug PL22, the conductive pattern 232, the conductive plug PL12, the conductive pattern 221_2, the conductive plug PL2, and the conductive pattern 104_2. FIG. 13 is an XY plan view illustrating a configuration near the shunt resistor element 8. FIGS. 14A and 14B are YZ cross-sectional views illustrating a current path in the vicinity of the shunt resistor element 8. FIG. 14A is a YZ cross-sectional view passing through the shunt resistor element 8, and illustrates a cross section of FIG. 13 taken along line D-D. FIG. 14B is a YZ cross-sectional view not passing through the shunt resistor element 8, and illustrates a cross section of FIG. 13 taken along line E-E.

The currents flowing through the conductive pattern 3, the shunt resistor element 8, the conductive pattern 104_1, the conductive pattern 221_1, the conductive pattern 231, the −X side portion of the conductive pattern 241, the +Y side portion of the conductive pattern 241, the +X side portion of the conductive pattern 241, the conductive pattern 232, the conductive pattern 221_2, and the conductive pattern 104_2 are denoted as I₂₁, I₂₂, I₂₃, I₂₄, I₂₅, I₂₆, I₂₇, I₂₈, I₂₉, I₃₀, and I₃₁, respectively.

The current I₂₁ flows mainly in the −Y direction. The current I₂₂ flows mainly in the −Y direction. The current I₂₃ flows mainly in the −Y direction. The current I₂₄ flows mainly in the +Y direction. The current I₂₅ flows mainly in the −Y direction. The current I₂₆ flows mainly in the +Y direction. The current I₂₇ flows mainly in the +X direction. The current I₂₈ flows mainly in the −Y direction. The current I₂₉ flows mainly in the +Y direction. The current I₃₀ flows mainly in the −Y direction. The current I₃₀ flows mainly in the +Y direction. The currents I₂₁ to I₂₄ form a substantially U-shaped current path in the vertical direction (YZ direction) with the +Y side opened. In this vertical current path, the current I₂₂ and the current I₂₄ are in opposite directions.

The current I₂₂ generates a clockwise magnetic flux H₂₂ when viewed from the +Y direction according to the parasitic inductive component LANT of the shunt resistor element 8. The current I₂₄ flows in a direction opposite to that of the current I₂₂, and generates a magnetic flux H₂₄ in the opposite direction. The current I₂₄ generates a clockwise magnetic flux H₁₇ when viewed from the −Y direction.

The currents I₂₁ to I₃₁ form a three-dimensional current path in which seven substantially U-shapes are combined. In this three-dimensional current path, in addition to the current I₂₂ and the current I₂₄ being in opposite directions, the current I₂₂ and the current I₂₆ are in opposite directions, the current I₂₂ and the current I₂₉ are in opposite directions, and the current I₂₂ and the current I₃₁ are in opposite directions.

The current I₂₂ generates a clockwise magnetic flux H₂₂ when viewed from the +Y direction according to the parasitic inductive component L_{SNT} of the shunt resistor element 8. The current I₂₆ flows in a direction opposite to that of the current I₂₂, and generates a magnetic flux H₂₆ in the opposite direction. The current I₂₆ generates a clockwise magnetic flux H₂₆ when viewed from the −Y direction. The current I₂₉ flows in a direction opposite to that of the current I₂₂, and generates a magnetic flux H₂₉ in the opposite direction. The current I₂₉ generates a clockwise magnetic flux H₂₉ when viewed from the −Y direction. The current I₃₁ flows in a direction opposite to that of the current I₂₂, and generates a magnetic flux H₃₁ in the opposite direction. The current I₃₁ generates a clockwise magnetic flux H₃₁ when viewed from the −Y direction.

As a result, since the magnetic flux H₂₂ can be canceled by the magnetic flux H₂₆, the magnetic flux H₂₉, and the magnetic flux H₃₁ in addition to being canceled by the magnetic flux H₂₄, it is possible to further weaken the parasitic inductive component L_{SNT} of the shunt resistor element 8 equivalently.

As described above, in the third embodiment, the power module 101 forms a large number of currents in the opposite direction to the current flowing through the shunt resistor element 8 in the three-dimensional current path using the multi wiring layers, and may cancel the magnetic flux by the current of the shunt resistor element 8 with the magnetic flux by the large number of currents in the opposite direction. As a result, the parasitic inductive component L_{SNT} of the shunt resistor element 8 can be further weakened, and the detection accuracy of the voltage across the shunt resistor element 8 by the voltage sensor VS can be further improved. Accordingly, the detection accuracy of the current flowing through the shunt resistor element 8 can be further improved.

### Fourth Embodiment

Next, a power module according to a fourth embodiment will be described. Hereinafter, portions different from those of the first to third embodiments will be mainly described.

Although in the first to third embodiments, a configuration in which the reverse current is generated by devising the arrangement of the shunt resistor element 8 with respect to the multiple conductive patterns is exemplified, in the fourth embodiment, a configuration in which the reverse current is generated by devising the mounting of the shunt resistor element 8 with respect to the conductive pattern is exemplified.

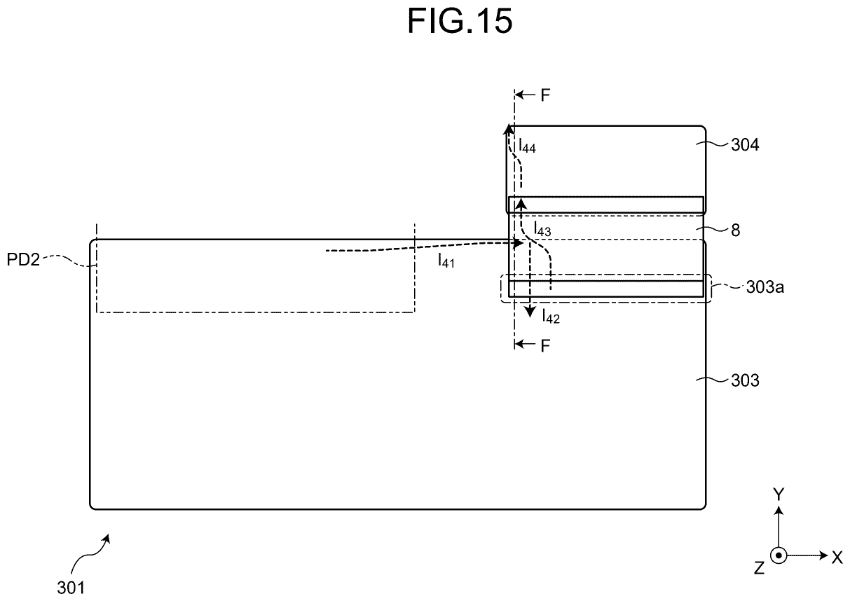

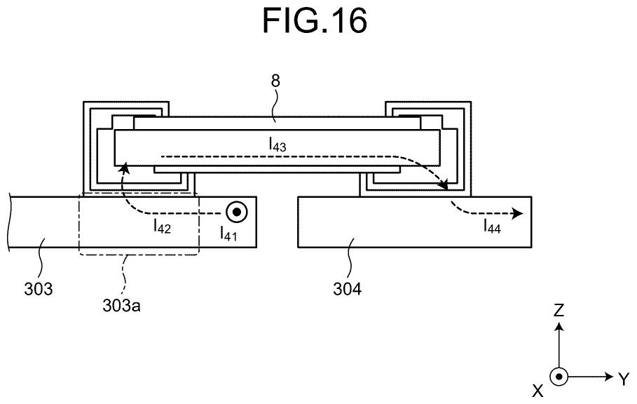

For example, in a power module 301, as illustrated in FIGS. 15 and 16, a current path having a substantially U shape in a YZ cross-sectional view may be formed by the conductive pattern 303 and the shunt resistor element 8. FIG. 15 is an XY plan view illustrating a current path in the vicinity of the shunt resistor element 8. FIG. 16 is a YZ cross-sectional view illustrating a current path in the vicinity of the shunt resistor element 8, and illustrates a cross section of FIG. 15 taken along line F-F.

In the power module 301, the wiring layer L1 includes a conductive pattern 303 and a conductive pattern 304. The power device PD2 and the shunt resistor element 8 are disposed in the wiring layer L1.

The power device PD2 and the shunt resistor element 8 are disposed apart from each other in the X direction. The Y position of the power device PD2 may include the Y position of the shunt resistor element 8.

The conductive pattern 303 is connected to the −Y side end portion of the power device PD2 and the −Y side end portion of the shunt resistor element 8. The conductive pattern 303 is electrically connected between the power device PD2 and the shunt resistor element 8. In the conductive pattern 303, one end on the +Y side is connected to the power device PD2 on the −X side, and a portion 303a located slightly on the −Y side from one end on the +Y side is connected to one end of the shunt resistor element 8 on the +X side.

The shunt resistor element 8 is electrically connected between the conductive pattern 303 and the conductive pattern 304 in the Y direction. In the shunt resistor element 8, one end on the −Y side is connected to the portion 303a located slightly on the −Y side from the end portion on the +Y side of the conductive pattern 303, and the other end on the +Y side is connected to one end of the conductive pattern 304.

The conductive pattern 304 is electrically connected to the other end of the shunt resistor element 8 in the Y direction. One end of the conductive pattern 304 on the −Y side is connected to the other end of the shunt resistor element 8.

A current flowing along one end on the +X side of the conductive pattern 303 is denoted by I₄₁, a current flowing from one end on the +Y side of the conductive pattern 303 to the portion 303a is denoted by I₄₂, a current flowing through the shunt resistor element 8 is denoted by I₄₃, and a current flowing through the conductive pattern 304 is denoted by I₄₄. A substantially U-shaped current path in the vertical direction (YZ direction) is formed by the currents I₄₁ to I₄₄.

The current I₄₁ flows mainly in the +X direction. The current I₄₂ flows mainly in the −Y direction. The current I₄₃ flows mainly in the +Y direction. The current I₄₄ flows mainly in the +Y direction. In this vertical current path, the current I₄₃ is opposite to the current I₄₂.

The current I₄₃ generates a clockwise magnetic flux H₄₃ when viewed from the +Y direction according to the parasitic inductive component L_{SNT} of the shunt resistor element 8. The current I₄₂ flows in a direction opposite to that of the current I₄₃, and generates a magnetic flux H₄₃ in the opposite direction. The current I₄₃ generates a clockwise magnetic flux H₄₃ when viewed from the −Y direction.

As a result, since the magnetic flux H₄₃ can be canceled by the magnetic flux H₄₂, the parasitic inductive component L_{SNT} of the shunt resistor element 8 can be equivalently weakened.

As described above, in the fourth embodiment, in the power module 301, one end on the −Y side of the shunt resistor element 8 is connected to the portion 303a located slightly on the −Y side with respect to the +Y side end portion of the conductive pattern 303. As a result, in the current path flowing through the conductive pattern 303 and the shunt resistor element 8, a current in a direction opposite to the current flowing through the shunt resistor element 8 is formed, and the magnetic flux due to the current of the shunt resistor element 8 may be canceled by the magnetic flux due to the current in the direction opposite to the current. As a result, the parasitic inductive component L_{SNT} of the shunt resistor element 8 can be weakened, and the detection accuracy of the voltage across the shunt resistor element 8 by the voltage sensor VS can be improved. Accordingly, the detection accuracy of the current flowing through the shunt resistor element 8 can be improved.

### Fifth Embodiment

Next, a power module according to a fifth embodiment will be described. Hereinafter, portions different from those of the first to fourth embodiments will be mainly described.

Although in the third embodiment and the fourth embodiment, a configuration in which one reverse current is generated by devising mounting of the shunt resistor element 8 on the conductive pattern is exemplified, in the fifth embodiment, a configuration in which multiple reverse currents is generated by devising mounting of the shunt resistor element 8 on the conductive pattern is exemplified.

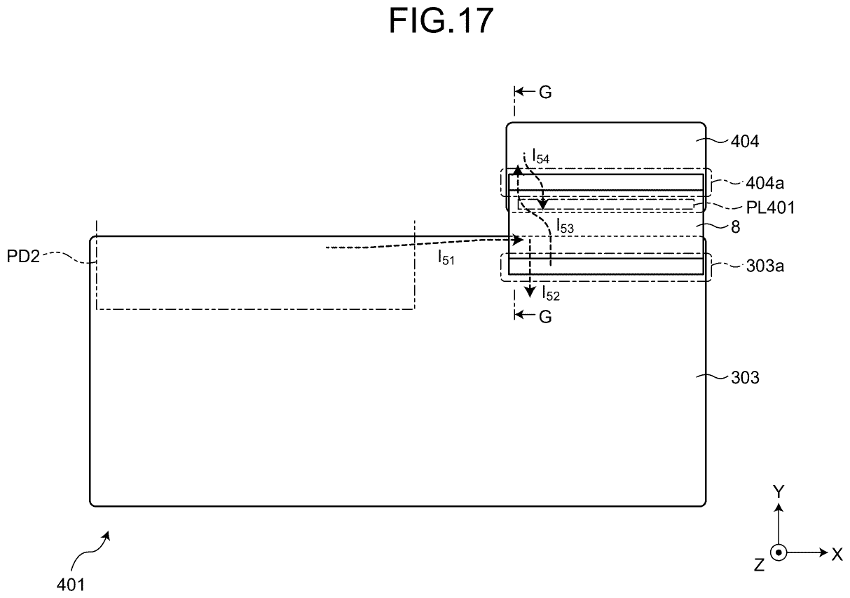

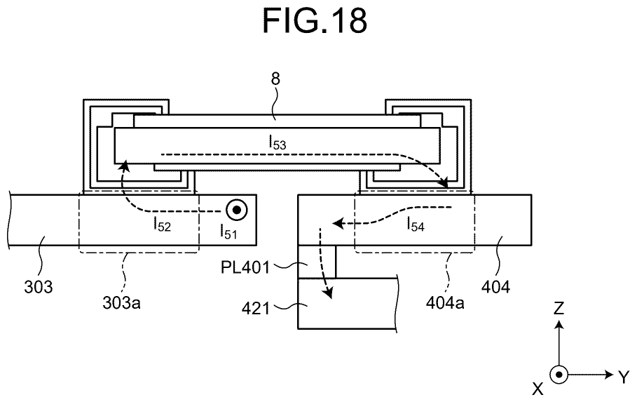

For example, in a power module 401, as illustrated in FIGS. 17 and 18, multiple substantially U-shaped current paths may be formed in the YZ cross-sectional view by the conductive patterns 303 and 304 and the shunt resistor element 8. FIG. 17 is an XY plan view illustrating a current path in the vicinity of the shunt resistor element 8. FIG. 18 is a YZ cross-sectional view illustrating a current path in the vicinity of the shunt resistor element 8, and illustrates a cross section of FIG. 17 taken along line G-G.

In the power module 401, the wiring layer L1 includes a conductive pattern 404 instead of the conductive pattern 304 (see FIG. 15). The wiring layer L2 includes a conductive pattern 421. The conductive plug PL401 is disposed between the wiring layer L1 and the wiring layer L2.

The shunt resistor element 8 is electrically connected between the conductive pattern 303 and the conductive pattern 404 in the Y direction. In the shunt resistor element 8, one end on the −Y side is connected to the portion 303a, and the other end on the +Y side is connected to a portion 404a. The portion 303a is located slightly on the −Y side from the +Y side end portion of the conductive pattern 303. The portion 404a is located slightly on the +Y side from the −Y side end portion of the conductive pattern 404.

The conductive pattern 404 is electrically connected to the other end of the shunt resistor element 8 in the Y direction. The conductive pattern 404 is connected between the shunt resistor element 8 and the conductive plug PL401 in the Z direction. In the conductive pattern 404, the portion 404a located slightly on the +Y side from one end on the −Y side is connected to the other end of the shunt resistor element 8.

As illustrated in FIG. 18, the conductive plug PL401 is disposed between the conductive pattern 404 and the conductive pattern 421 in the Z direction. The conductive plug PL401 is electrically connected between the conductive pattern 404 and the conductive pattern 421. In the conductive plug PL401, one end on the +Z side is connected to one end on the −Y side of the conductive pattern 404, extends in the Z direction, and the other end on the −Z side is connected to the conductive pattern 421.

The other end of the conductive plug PL401 on the −Z side is connected to the conductive pattern 421. The conductive pattern 421 is electrically connected to the conductive pattern 404 via the conductive plug PL401.

A current flowing along one end on the +X side of the conductive pattern 303 is denoted by I₅₁, a current flowing from one end on the +Y side of the conductive pattern 303 to the portion 303a is denoted by I₅₂, a current flowing through the shunt resistor element 8 is denoted by I₅₃, and a current flowing through the conductive pattern 404 is denoted by I₅₄. A substantially U-shaped current path in the vertical direction (YZ direction) is formed by the currents I₅₁ to I₅₄.

The current I₅₁ flows mainly in the +X direction. The current I₅₂ flows mainly in the −Y direction. The current I₅₃ flows mainly in the +Y direction. The current I₅₄ flows mainly in the −Y direction. In the vertical current path, the current I₅₃ is in the direction opposite to the current I₅₂, and is in the direction opposite to the current I₅₄.

The current I₅₃ generates a clockwise magnetic flux H₅₃ when viewed from the +Y direction according to the parasitic inductive component L_{SNT} of the shunt resistor element 8. The current I₅₂ flows in a direction opposite to that of the current I₅₃, and generates a magnetic flux H₅₂ in the opposite direction. The current I₅₂ generates a clockwise magnetic flux H₅₂ when viewed from the −Y direction. The current I₅₄ flows in a direction opposite to that of the current I₅₃, and generates a magnetic flux H₅₄ in the opposite direction. The current I₅₄ generates a clockwise magnetic flux H₅₄ when viewed from the −Y direction.

As a result, since the magnetic flux H₅₃ can be canceled by the multiple magnetic fluxes H₅₂ and H₅₄, it is possible to further weaken the parasitic inductive component L_{SNT} of the shunt resistor element 8 equivalently.

As described above, in the fifth embodiment, in the power module 401, one end on the −Y side of the shunt resistor element 8 is connected to the portion 303a located slightly on the −Y side with respect to the +Y side end portion of the conductive pattern 303. The other end on the +Y side of the shunt resistor element 8 is connected to the portion 404a located slightly on the +Y side from the end portion on the −Y side of the conductive pattern 404. As a result, in the current path flowing through the conductive pattern 303, the shunt resistor element 8, and the conductive pattern 404, multiple currents in the opposite directions to the current flowing through the shunt resistor element 8 is formed, and the magnetic flux due to the current of the shunt resistor element 8 may be canceled by the magnetic flux due to the multiple currents in the opposite directions. As a result, the parasitic inductive component L_{SNT} of the shunt resistor element 8 can be further weakened, and the detection accuracy of the voltage across the shunt resistor element 8 by the voltage sensor VS can be further improved. Accordingly, the detection accuracy of the current flowing through the shunt resistor element 8 can be further improved.

### Sixth Embodiment

Next, a power module according to a sixth embodiment will be described. Hereinafter, portions different from those of the first to fifth embodiments will be mainly described.

Although in the fourth embodiment and the fifth embodiment, a configuration in which a reverse current is generated by devising mounting of the shunt resistor element 8 on the conductive pattern is exemplified, in the sixth embodiment, a configuration in which a reverse current is generated by devising the pattern of the shunt resistor element 508 is exemplified.

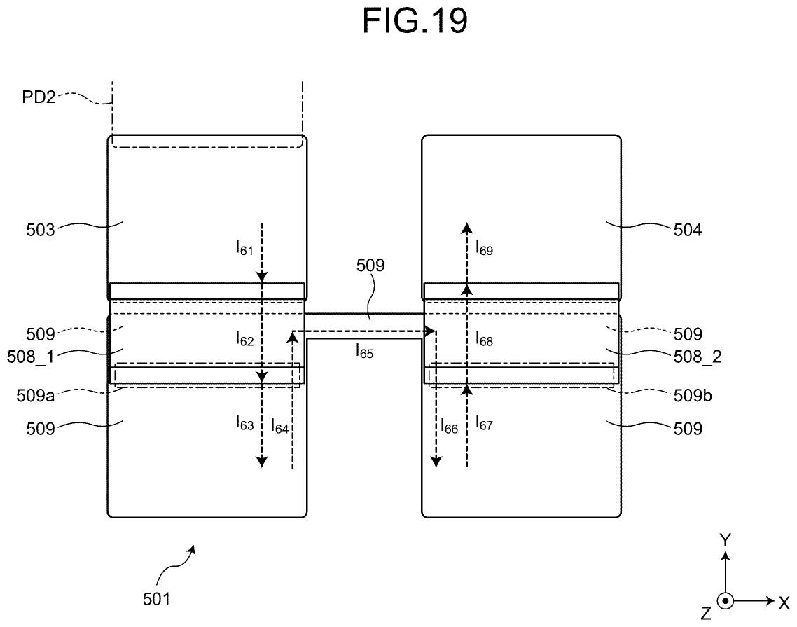

For example, in a power module 501, as illustrated in FIG. 19, a current path having a substantially U shape in XY view may be formed by arranging multiple shunt resistor elements and conductive patterns. FIG. 19 is an XY plan view illustrating a current path in the vicinity of the shunt resistor elements 508_1 and 508_2.

In the power module 501, the wiring layer L1 includes a conductive pattern 503 and conductive patterns 504 and 509. In the wiring layer L1, the power device PD2 and two shunt resistor elements 508_1 and 508_2 are disposed.

The shunt resistor element 508_1 and the shunt resistor element 508_2 are separated from each other in the X direction. The shunt resistor element 508_1 and the shunt resistor element 508_2 are electrically connected in series via the conductive pattern 509. In the XY plan view, the configuration including the shunt resistor element 508_1, the conductive pattern 509, and the shunt resistor element 508_2 forms a substantially U-shaped current path. The shunt resistor element 508_1 and the shunt resistor element 508_2 equivalently function as one shunt resistor element having a resistance value obtained by adding the resistance values of the both shunt resistor elements.

The shunt resistor element 508_1 is electrically connected between the conductive pattern 503 and the conductive pattern 509 in the Y direction. The shunt resistor element 508_1 may have a substantially rectangular shape in XY plan view. The longitudinal direction of the shunt resistor element 508_1 may be the X direction. In the shunt resistor element 508_1, one end on the −Y side is connected to the end portion on the −Y side of the conductive pattern 503, and the other end on the +Y side is connected to a portion 509a. The portion 509a is located slightly on the −Y side from the end portions on the −X side and the +Y side of the conductive pattern 509.

The shunt resistor element 508_2 is electrically connected between the conductive pattern 504 and the conductive pattern 509 in the Y direction. The shunt resistor element 508_1 may have a substantially rectangular shape in XY plan view. The longitudinal direction of the shunt resistor element 508_1 may be the X direction. In the shunt resistor element 508_1, one end on the −Y side is connected to a portion 509b, and the other end on the +Y side is connected to the end portion on the −Y side of the conductive pattern 504. The portion 509b is located slightly on the −Y side from the end portions on the −X side and the +Y side of the conductive pattern 509.

The conductive pattern 503 is connected to the −Y-side end portion of the power device PD2 and the +Y side of the shunt resistor element 508_1. The conductive pattern 503 is electrically connected between the power device PD2 and the shunt resistor element 508_1. The conductive pattern 503 is disposed apart from the conductive pattern 504 on the −X side. The conductive pattern 503 may have a substantially rectangular shape in XY plan view. One end of the conductive pattern 503 on the −Y side is electrically connected to one end of the shunt resistor element 8 in the Y direction.

The conductive pattern 504 is disposed on the +Y side of the shunt resistor element 508_2 and is disposed apart from the +X side of the conductive pattern 503. The conductive pattern 504 may have a substantially rectangular shape in XY plan view. One end of the conductive pattern 504 on the −Y side is electrically connected to one end of the shunt resistor element 8 in the Y direction.

The conductive pattern 509 is arranged substantially on the −Y side with respect to the shunt resistor element 508_1 and the shunt resistor element 508_2, and a part thereof is arranged between the shunt resistor element 508_1 and the shunt resistor element 508_2. The conductive pattern 509 is electrically connected between the shunt resistor element 508_1 and the shunt resistor element 508_2.

The conductive pattern 509 forms a substantially U-shape with the −Y side opened in XY plan view. The conductive pattern 509 extends in the Y direction from the portion 509a to reach end portions on the −X side and the +Y side, extends in the X direction from end portions on the −X side and the +Y side to reach end portions on the +X side and the +Y side, and extends in the Y direction from end portions on the +X side and the +Y side to reach the portion 509b.

In the conductive pattern 509, the portion 509a located slightly on the −Y side from the end portions on the −X side and the +Y side is connected to the other end of the shunt resistor element 508_1. In the conductive pattern 509, the portion 509b located slightly on the −Y side from the end portions on the +X side and the +Y side is connected to one end of the shunt resistor element 508_2.

The current flowing through the conductive pattern 503 is denoted by I₆₁, the current flowing through the shunt resistor element 508_1 is denoted by I₆₂, the current flowing through the portion 509a of the conductive pattern 509 is denoted by I₆₃, the current flowing from the portion 509a of the conductive pattern 509 to the −X side and +Y side end portions is denoted by I₆₄, the current flowing from the −X side and +Y side end portions of the conductive pattern 509 to the +X side and +Y side end portions is denoted by I₆₅, the current flowing from the +X side and +Y side end portions of the conductive pattern 509 to the portion 509b is denoted by I₆₆, the current flowing through the portion 509b of the conductive pattern 509 is denoted by I₆₇, the current flowing through the shunt resistor element 508_2 is denoted by I₆₈, and the current flowing through the conductive pattern 504 is denoted by I₆₉. By the currents I₆₁ to I₆₉, a current path combining three substantially U-shapes is formed.

The current I₆₁ flows mainly in the −Y direction. The current I₆₂ flows mainly in the −Y direction. The current I₆₃ flows mainly in the −Y direction. The current I₆₄ flows mainly in the +Y direction. The current I₆₅ flows mainly in the +X direction. The current I₆₆ flows mainly in the −Y direction. The current I₆₇ flows mainly in the +Y direction. The current I₆₈ flows mainly in the +Y direction. The current I₆₉ flows mainly in the +Y direction.

In the current path obtained by combining the three substantially U shapes, the current I₆₂ is in a direction opposite to the currents I₆₄, I₆₇, I₆₈, and I₆₉.

The current I₆₂ generates a clockwise magnetic flux H₆₂ when viewed from the +Y direction according to the parasitic inductive component of the shunt resistor element 508_1. The current I₆₄ flows in a direction opposite to that of the current I₆₂, and generates a magnetic flux H₆₄ in the opposite direction. The current I₆₄ generates a clockwise magnetic flux H₆₄ when viewed from the −Y direction. The current I₆₇ flows in a direction opposite to that of the current I₆₂, and generates a magnetic flux H₆₇ in the opposite direction. The current I₆₇ generates a clockwise magnetic flux H₆₇ when viewed from the −Y direction. The current I₆₈ flows in a direction opposite to that of the current I₆₂, and generates a magnetic flux H₆₈ in the opposite direction. The current I₆₈ generates a clockwise magnetic flux H₆₈ when viewed from the −Y direction. The current I₆₉ flows in a direction opposite to that of the current I₆₂, and generates a magnetic flux H₆₉ in the opposite direction. The current I₆₉ generates a clockwise magnetic flux H₆₉ when viewed from the −Y direction.

As a result, since the magnetic flux H₆₂ can be canceled by the multiple magnetic fluxes H₆₄, H₆₇, H₆₈, and H₆₉, it is possible to further weaken the parasitic inductive component of the shunt resistor element 508_1 equivalently.

In the current path obtained by combining the three substantially U shapes, the current I₆₈ is in a direction opposite to the currents I₆₁, I₆₂, I₆₃, and I₆₆.

The current I₆₈ generates a clockwise magnetic flux H₆₈ when viewed from the +Y direction according to the parasitic inductive component of the shunt resistor element 508_2. The current I₆₁ flows in a direction opposite to that of the current I₆₈, and generates a magnetic flux H₆₁ in the opposite direction. The current I₆₁ generates a clockwise magnetic flux H₆₁ when viewed from the −Y direction. The current I₆₂ flows in a direction opposite to that of the current I₆₈, and generates a magnetic flux H₆₂ in the opposite direction. The current I₆₂ generates a clockwise magnetic flux H₆₂ when viewed from the −Y direction. The current I₆₃ flows in a direction opposite to that of the current I₆₈, and generates a magnetic flux H₆₃ in the opposite direction. The current I₆₃ generates a clockwise magnetic flux H₆₃ when viewed from the −Y direction. The current I₆₆ flows in a direction opposite to that of the current I₆₈, and generates a magnetic flux H₆₆ in the opposite direction. The current I₆₆ generates a clockwise magnetic flux H₆₆ when viewed from the −Y direction.

As a result, since the magnetic flux H₆₈ can be canceled by the multiple magnetic fluxes H₆₁, H₆₂, H₆₃, and H₆₆, it is possible to further weaken the parasitic inductive component of the shunt resistor element 508_2 equivalently.

As described above, in the sixth embodiment, the power module 501 includes the multiple shunt resistor elements 508_1 and 508_2. In a current path flowing through the conductive pattern 503, the shunt resistor element 508_1, the conductive pattern 509, the shunt resistor element 508_2, and the conductive pattern 504, multiple currents in a direction opposite to the current flowing through the shunt resistor element 508_1 is formed, and multiple currents in a direction opposite to the current flowing through the shunt resistor element 508_2 is formed. As a result, as compared with the case of including a single shunt resistor element, the number of combinations of reverse currents can be increased, and the magnetic flux by the shunt resistor elements 508_1 and 508_2 can be efficiently canceled by the magnetic flux by a larger number of reverse currents. As a result, the parasitic inductive component LINT of the shunt resistor element 508 can be further weakened, and the detection accuracy of the voltage across the shunt resistor element 508 by the voltage sensor VS can be further improved. Accordingly, the detection accuracy of the current flowing through the shunt resistor element 508 can be further improved.

Note that the observation node of the voltage sensor VS may be both ends of any shunt resistor element (for example, both ends of the shunt resistor element 508_1 or both ends of the shunt resistor element 508_2), or may be both ends of the series connection of the multiple shunt resistor elements 508_1 and 508_2. The number of shunt resistor elements is not limited to two, and may be three or more.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power module comprising:
a power device;
a first conductive pattern having one end connected to the power device and extending from the power device in at least a first direction;
a shunt resistor element having one end in the first direction connected to an other end of the first conductive pattern; and
a second conductive pattern electrically connected to an other end of the shunt resistor element and including a portion extending in the first direction along the shunt resistor element and the first conductive pattern from a position separated from the shunt resistor element in a second direction intersecting the first direction.

2. The power module according to claim 1, wherein
a substantially U-shaped current path passing through the first conductive pattern, the shunt resistor element, and the second conductive pattern is formed.

3. The power module according to claim 2, wherein
the second conductive pattern is connected to the other end of the shunt resistor element in the first direction, extends from the other end of the shunt resistor element to the position separated in the second direction, is bent from the position separated, and extends in the first direction along the shunt resistor element and the first conductive pattern.

4. The power module according to claim 1, wherein
a current path which is a current path passing through the first conductive pattern, the shunt resistor element, and the second conductive pattern and in which multiple substantially U shapes is three-dimensionally combined is provided.

5. The power module according to claim 4, further comprising:
a third conductive pattern connected to the other end of the shunt resistor element in the first direction;
a first conductive plug having one end connected to the third conductive pattern and extending from the third conductive pattern in a third direction intersecting the first direction and the second direction; and
a fourth conductive pattern having one end connected to the other end of the first conductive plug and extending in the first direction from the other end of the first conductive plug.

6. The power module according to claim 5, wherein
the fourth conductive pattern extends from the other end of the first conductive plug to a position corresponding to the first conductive pattern in the first direction, is bent from the position corresponding to the first conductive pattern, and extends in the first direction along the first conductive pattern and the shunt resistor element.

7. The power module according to claim 6, further comprising
a second conductive plug having one end connected to an other end of the fourth conductive pattern, extending in the third direction from the fourth conductive pattern, and having the other end electrically connected to the second conductive pattern.

8. The power module according to claim 5, further comprising:
a third conductive plug having one end connected to the other end of the fourth conductive pattern and extending in the third direction from the fourth conductive pattern; and
a fifth conductive pattern having one end connected to an other end of the third conductive plug and extending from the other end of the third conductive plug in the first direction along the first conductive pattern and the shunt resistor element.

9. The power module according to claim 8, further comprising:
a fourth conductive plug having one end connected to an other end of the fifth conductive pattern and extending in the third direction from the fifth conductive pattern; and
a sixth conductive pattern having one end connected to an other end of the first conductive plug, extending from the other end of the first conductive plug in the first direction to a position corresponding to the first conductive pattern, bent from the position corresponding to the first conductive pattern, and extending in the first direction along the first conductive pattern and the shunt resistor element.

10. The power module according to claim 9, further comprising:
a fifth conductive plug having one end connected to an other end of the sixth conductive pattern and extending in the third direction from the sixth conductive pattern; and
a seventh conductive pattern connected to an other end of the fifth conductive plug and extending from the other end of the fifth conductive plug in the first direction along the shunt resistor element and the first conductive pattern.

11. The power module according to claim 9, further comprising:
a sixth conductive plug having one end connected to an other end of the seventh conductive pattern and extending in the third direction from the seventh conductive pattern; and
an eighth conductive pattern connected to an other end of the sixth conductive plug and extending in the first direction from the other end of the sixth conductive plug along the first conductive pattern and the shunt resistor element.

12. The power module according to claim 11, further comprising
a seventh conductive plug having one end connected to an other end of the eighth conductive pattern, extending in the third direction from the eighth conductive pattern, and having an other end electrically connected to the second conductive pattern.

13. A power module comprising:
a power device;
a first conductive pattern having one end connected to the power device and extending from the power device in a first direction and a second direction intersecting the first direction;
a shunt resistor element having one end in the first direction connected to a portion located inside in the first direction from one end of the first conductive pattern at a position separated from the power device in the second direction; and
a second conductive pattern connected to an other end of the shunt resistor element.

14. The power module according to claim 13, wherein
a substantially U-shaped current path passing through the first conductive pattern and the shunt resistor element is formed.

15. The power module according to claim 13, wherein
the other end of the shunt resistor element is connected to a portion located inside in the first direction from one end of the second conductive pattern.

16. The power module according to claim 13, wherein
a substantially U-shaped current path passing through the shunt resistor element and the second conductive pattern is formed.

17. The power module according to claim 16 further comprising
a conductive plug connected to one end of the second conductive pattern, the conductive plug extending from one end of the second conductive pattern toward a third direction, the third direction intersecting the first direction and the second direction.

18. A power module comprising:
a power device;
a first conductive pattern having one end connected to the power device;
a second conductive pattern disposed apart from the first conductive pattern in a first direction;
a first shunt resistor element having one end in a second direction connected to the first conductive pattern;
a second shunt resistor element having one end in the second direction connected to the second conductive pattern;
a third conductive pattern disposed between the first shunt resistor element and the second shunt resistor element in the first direction;
a fourth conductive pattern connected to an other end of the first shunt resistor element; and
a fifth conductive pattern connected to an other end of the second shunt resistor element.

19. The power module according to claim 18, wherein
a current path which is a current path passing through the first conductive pattern, the first shunt resistor element, the fourth conductive pattern, the third conductive pattern, the fifth conductive pattern, the second shunt resistor element, and the second conductive pattern and in which multiple substantially U-shaped shapes is two-dimensionally combined is formed.

20. The power module according to claim 19, wherein
the third conductive pattern is connected between the fourth conductive pattern and the fifth conductive pattern, extends from the fourth conductive pattern along the first shunt resistor element in the second direction to a position corresponding to the first shunt resistor element, is bent from a position corresponding to the first shunt resistor element, extends to a position corresponding to the second shunt resistor element in the first direction, is bent from a position corresponding to the second shunt resistor element, and extends to the fifth conductive pattern in the first direction.
